(19) United States
(12) Patent Application Publication
(10) Pub. No.: US 2009/0042402 A1
(43) Pub. Date: Feb. 12, 2009

(54) METHOD FOR FABRICATING SEMICONDUCTOR DEVICE

(75) Inventor: Hiroshi MORIOKA, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU MICROELECTRONICS LIMITED, Tokyo (JP)

(21) Appl. No.: 12/236,122

(22) Filed: Sep. 23, 2008

Related U.S. Application Data
(63) Continuation of application No. PCT/JP2006/306914, filed on Mar. 31, 2006.

(51) Int. Cl. H01L 21/31

(52) U.S. Cl. 438/762; 257/E21.24

(57) ABSTRACT

A semiconductor device fabrication method by which a desired pattern can be formed. After a conductive layer which is a material for a gate electrode is formed, a SiN layer to be used as a hard mask is formed. Then a photoresist layer is formed as a second mask. Then patterning is performed on the photoresist layer. Then patterning is performed on the SiN layer with the photoresist layer as a mask. After the photoresist layer is removed, surface portions of the SiN layer are transmuted and are selectively removed. The conductive layer under the SiN layer is etched with the reduced SiN layer as the hard mask. By doing so, the photoresist layer does not, for example, deform during the process and a minute gate electrode pattern can be formed stably.

This application is a continuing application, filed under 35 U.S.C. §111(a), of International Application PCT/JP2006/306914, filed on Mar. 31, 2006.

### BACKGROUND OF THE INVENTION

(1) Field of the Invention

This invention relates to a semiconductor device fabrication method and, more particularly, to a semiconductor device fabrication method using photolithography.

(2) Description of the Related Art

The technique of treating various layers, such as a polycrystalline silicon (poly-Si) layer, a silicon dioxide (SiO₂) layer, and a silicon nitride (SiN) layer, to be etched by reactive ion etching (RIE) with a photoresist pattern formed by photolithography as a mask is generally used in the present semiconductor device manufacture.

By the way, as a pattern becomes minuter, a light source used for the photolithography is changing from a krypton fluoride (KrF) exima laser (having a wavelength of 248 nm) to an argon fluoride (ArF) exima laser (having a wavelength of 193 nm). That is to say, a light source having a shorter wavelength is used. The wavelength of a light source for exposure has become shorter, so a photoresist material itself is properly changed in order to obtain sufficient transmissivity for light emitted by such a light source.

The minimum dimension that can be realized exists in the photolithography because of limitations of an exposure wavelength. With a gate electrode of a MOS transistor, a bit line of a DRAM, or the like, however, a pattern the dimension of which is smaller than or equal to the minimum dimension is required in order to increase memory density. For example, a minute line pattern having a width of 100 nm or less is required even in the 90 nm node generation.

In recent years a technique called resist trimming has generally been used in order to realize such minute line patterns. With this technique, a photoresist pattern is narrowed down to the limit dimension or less by isotropic etching using plasma of, for example, sulfur dioxide (SO₂) (see, for example, Japanese Unexamined Patent Publication No. 2004-152784).

However, photoresist used in the case of using an ArF exima laser as a light source for exposure has low resistance to plasma. It may be possible to form a minute photoresist pattern by trimming. However, if the dimension of a photoresist pattern is 100 nm or less, the mechanical strength itself is low. Accordingly, if RIE is performed, the following problems, for example, arise. A minute photoresist pattern comes down, edge roughness increases, or a photoresist pattern deforms. In addition, a photoresist pattern comes down or deforms because of thermal stress or static electricity caused by RIE. A method for solving these problem should be established.

### SUMMARY OF THE INVENTION

The present invention was made under the background circumstances described above. An object of the present invention is to provide a semiconductor device fabrication method in which a desired pattern can be formed by the photolithography.

In order to achieve the above object, a semiconductor device fabrication method comprising the steps of forming a first mask layer over a conductive layer, forming a second mask layer over the first mask layer, performing patterning on the second mask layer, performing patterning on the first mask layer by the use of the second mask layer patterned, transmuting exposed surface portions of the first mask layer, reducing the first mask layer by removing the transmuted surface portions, and performing patterning on the conductive layer by the use of the reduced first mask layer is provided.

The above and other objects, features and advantages of the present invention will become apparent from the following description when taken in conjunction with the accompanying drawings which illustrate preferred embodiments of the present invention by way of example.

### BRIEF DESCRIPTION OF THE DRAWINGS

FIG. 1 is an example of a view for describing the basic principles of forming a gate electrode.

FIG. 2 is an example of a fragmentary sectional view of a CMOSFET according to a first embodiment of the present invention.

FIG. 3 is an example of a view for describing the principles of fabricating the CMOSFET according to the first embodiment of the present invention.

FIG. 4 is an example of a fragmentary sectional view showing the step of forming an nMOS region and a pMOS region.

FIG. 5 is an example of a fragmentary sectional view showing the step of forming a poly-Si layer.

FIG. 6 is an example of a fragmentary sectional view showing the step of implanting impurities.

FIG. 7 is an example of a fragmentary sectional view showing the step of forming a hard mask.

FIG. 8 is an example of a fragmentary sectional view showing the step of forming gate electrodes.

FIG. 9 is an example of a fragmentary sectional view showing the step of forming side wall insulating films and source/drain regions.

FIG. 10 is an example of a fragmentary sectional view showing the step of forming silicide films.

FIG. 11 is an example of a view for describing the principles of the step of forming a gate electrode by a first method.

FIG. 12 is an example of a fragmentary sectional view showing the step of forming a photoresist layer.

FIG. 13 is an example of a fragmentary sectional view showing an etching step.

FIG. 14 is an example of a fragmentary sectional view showing the step of removing an anti-reflection coating and the photoresist layer.

FIG. 15 is an example of a fragmentary sectional view showing the step of forming an oxide film on the surface of a SiN layer.

FIG. 16 is an example of a fragmentary sectional view showing the step of forming a hard mask.

FIG. 17 is an example of a fragmentary sectional view showing the step of forming a gate electrode.

FIG. 18 is an example of a view for describing the principles of the step of forming a gate electrode by a second method.

FIG. 19 is an example of a fragmentary sectional view showing the step of forming a photoresist layer.

FIG. 20 is an example of a fragmentary sectional view showing an etching step.

FIG. 21 is an example of a fragmentary sectional view showing the step of forming an oxide film on the sides of a SiC layer.

FIG. 22 is an example of a fragmentary sectional view showing the step of forming a hard mask.

FIG. 23 is an example of a fragmentary sectional view showing the step of forming a gate electrode.

FIG. 24 is an example of a view for describing the principles of the step of forming a gate electrode by a third method.

FIG. 25 is an example of a fragmentary sectional view showing the step of forming a photoresist layer.

FIG. 26 is an example of a fragmentary sectional view showing an etching step.

FIG. 27 is an example of a fragmentary sectional view showing the step of removing the photoresist layer and an anti-reflection coating.

FIG. 28 is an example of a fragmentary sectional view showing the step of forming an oxide film on the sides of a SiC layer.

FIG. 29 is an example of a fragmentary sectional view showing the step of forming a hard mask.

FIG. 30 is an example of a fragmentary sectional view showing the step of forming a gate electrode.

FIG. 31 is an example of a fragmentary sectional view of a CMOSFET according to a second embodiment of the present invention.

FIG. 32 is an example of a view for describing the principles of fabricating the CMOSFET according to the second embodiment of the present invention.

FIG. 33 is an example of a fragmentary sectional view showing the step of implanting impurities.

FIG. 34 is an example of a fragmentary sectional view showing the step of forming source/drain regions.

### DESCRIPTION OF THE PREFERRED EMBODIMENTS

Embodiments of the present invention will now be described in detail with reference to the drawings. The formation of a gate electrode will be taken as an example.

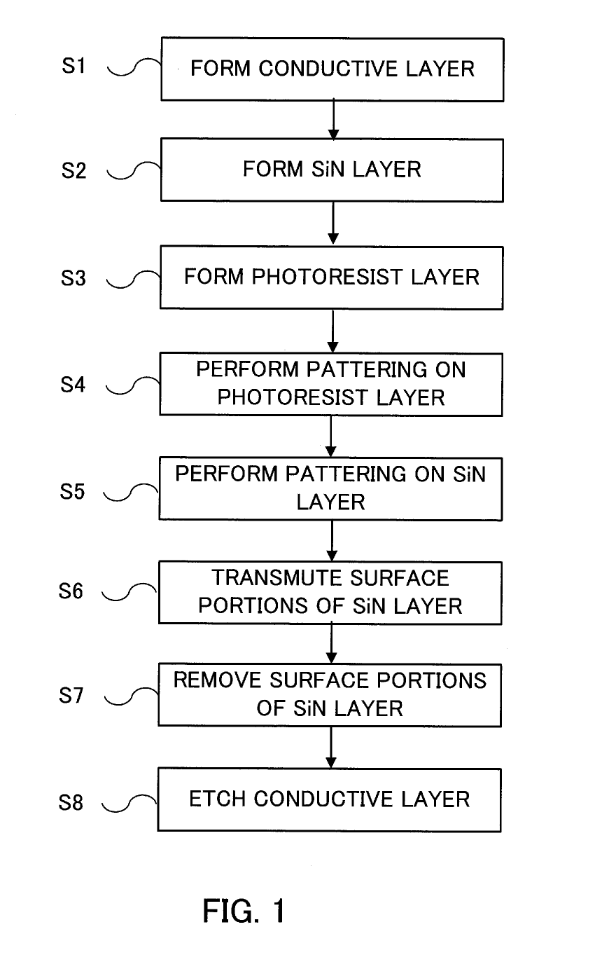

FIG. 1 is an example of a view for describing the basic principles of forming a gate electrode.

It is assumed that a gate electrode of a MOSFET is formed. A conductive layer is formed first over a gate insulating film over a substrate by the use of a gate electrode material, such as poly-Si (step S1). After that, a SiN layer to be used later as a hard mask at the time of the patterning of the gate electrode is formed as a first mask over the conductive layer (step S2). After the SiN layer is formed in this way, a photoresist layer with predetermined thickness is formed as a second mask over the SiN layer (step S3).

Then patterning is performed on the photoresist layer (step S4). At this time a pattern of the photoresist layer is formed at a position where the gate electrode is to be formed. The width of the pattern of the photoresist layer is set so that the pattern of the photoresist layer will not deform or come down during the process. The thickness of the photoresist layer formed in the above step S3 is set so that the pattern of the photoresist layer will not deform or come down after the patterning performed in step S4.

Then patterning is performed on the SiN layer under the photoresist with the photoresist layer after the patterning as a mask (step S5). After the photoresist layer is removed, surface portions of, at the least, the sides of the exposed SiN layer are transmuted (step S6) and are selectively removed (step S7). To transmute the surface portions of the SiN layer, the following method, for example, can be used. The surface portions are oxidized to form silicon oxide nitride (SiON) or SiO₂ there. In this case, the surface portions can selectively be etched by the use of, for example, hydrogen fluoride (HF). The width of the surface portions can be controlled by properly setting conditions under which the surface portions are transmuted.

By removing the surface portions of the SiN layer in this way, the width of the SiN layer becomes smaller than the width of the photoresist layer obtained by performing the patterning in the above step S4. The conductive layer under the SiN layer is etched with the reduced SiN layer as a hard mask (step S8).

With the above method, the width of the pattern of the photoresist layer formed can be made slightly larger than the width of the gate electrode to be finally formed. Patterning is performed on the SiN layer by the use of the pattern of the photoresist layer. Then the surface portions of the SiN layer are transmuted and removed. By doing so, the width of a pattern of the SiN layer is shrunk. The patterning of the gate electrode is performed with the shrunk pattern of the SiN layer as a hard mask. The above method makes it possible to form a minuter gate electrode pattern without, for example, deforming the photoresist layer during the process.

In the above example, the photoresist layer is formed over the SiN layer. However, the photoresist layer may be formed over an anti-reflection coating or the like formed over the SiN layer.

The above method will now be described in detail by giving a concrete example. The formation of a gate electrode of a CMOSFET will be taken as a concrete example.

A first embodiment of the present invention will be described first.

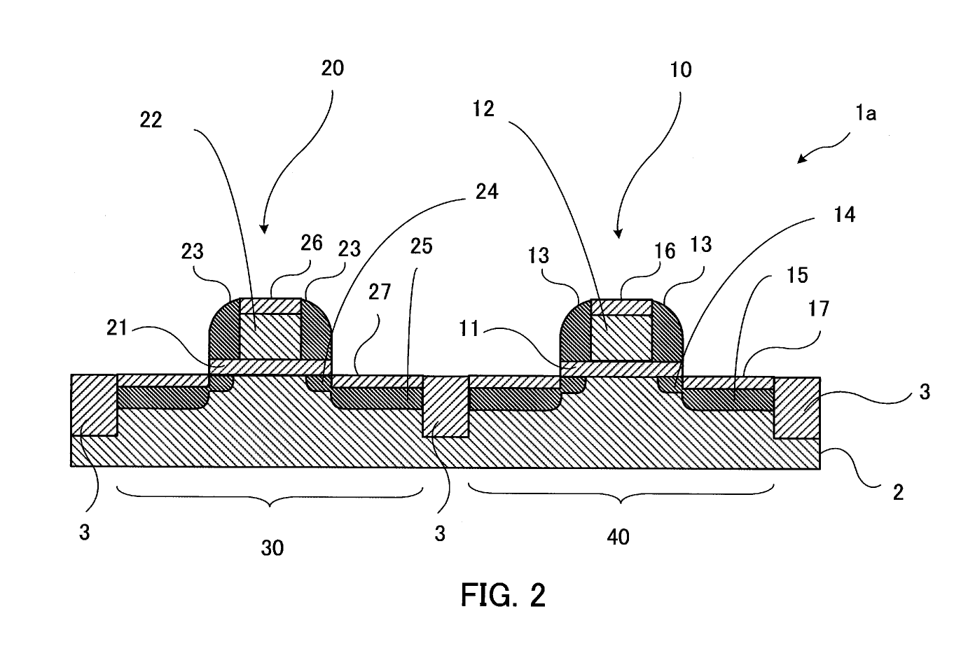

FIG. 2 is an example of a fragmentary sectional view of a CMOSFET according to a first embodiment of the present invention.

With a CMOSFET 1a shown in FIG. 2, shallow trench isolations (STIs) 3 are formed in a silicon (Si) substrate 2 to define an nMOS region 30 and a pMOS region 40. MOSFETs 20 and 10 are formed in the nMOS region 30 and the pMOS region 40 respectively.

The MOSFET 10 has a gate electrode 12 formed over the Si substrate 2 with a gate insulating film 11 between. A side wall insulating film 13 is formed outside the gate electrode 12. Source/drain extension regions 14 of a predetermined conduction type are formed on both sides of the gate electrode 12 in the Si substrate 2 directly under the side wall insulating film 13. In addition, source/drain regions 15 are formed on both sides of the side wall insulating film 13 in the Si substrate 2. A silicide film 16 is formed on the surface of the gate electrode 12. A silicide film 17 is formed over the source/drain regions 15.

The structure of the MOSFET 20 is the same as that of the MOSFET 10. That is to say, the MOSFET 20 has a laminated structure including a gate insulating film 21 and a gate electrode 22 over the Si substrate 2. A side wall insulating film 23 is formed outside the gate electrode 22. Source/drain extension regions 24 of a predetermined conduction type and source/drain regions 25 are formed in predetermined portions of the Si substrate 2. A silicide film 26 is formed on the surface of the gate electrode 22. A silicide film 27 is formed over the source/drain regions 25.

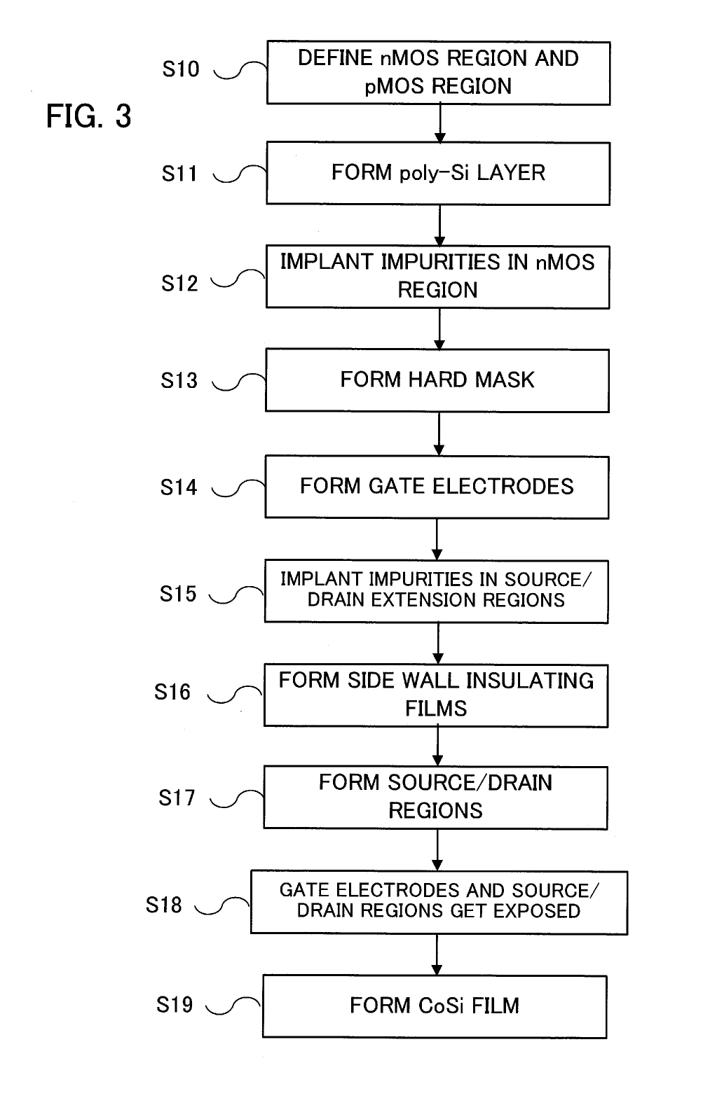

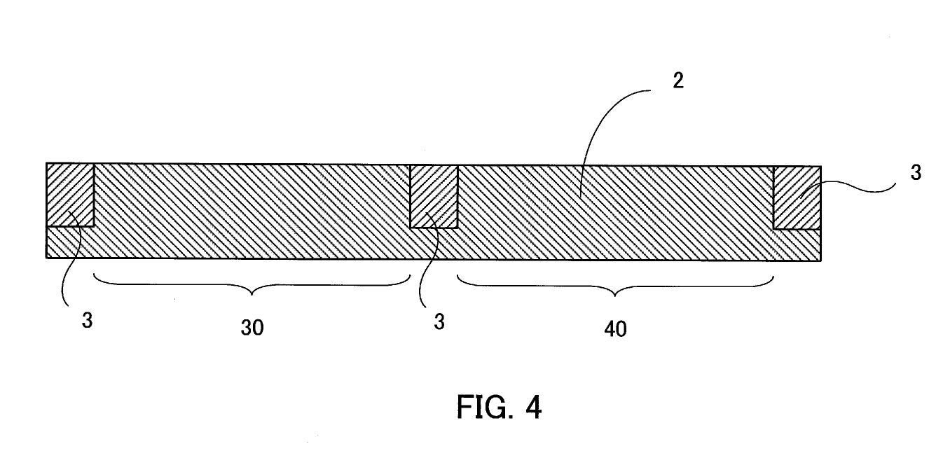

FIG. 3 is an example of a view for describing the principles of fabricating the CMOSFET according to the first embodiment of the present invention. Each of FIGS. 4 through 10 is an example of a fragmentary sectional view showing each step performed for fabricating the CMOSFET according to the first embodiment of the present invention.

The principles of fabricating the CMOSFET according to the first embodiment of the present invention shown in FIG. 3, together with each step which is performed for fabricating the CMOSFET according to the first embodiment of the present invention and which is shown in FIGS. 4 through 10, will now be described in detail.

FIG. 4 is an example of a fragmentary sectional view showing the step of forming the nMOS region and the pMOS region.

To isolate one element from the other element, the STIs 3 are formed first in the Si substrate 2 and the nMOS region 30 and the pMOS region 40 are defined (step S10).

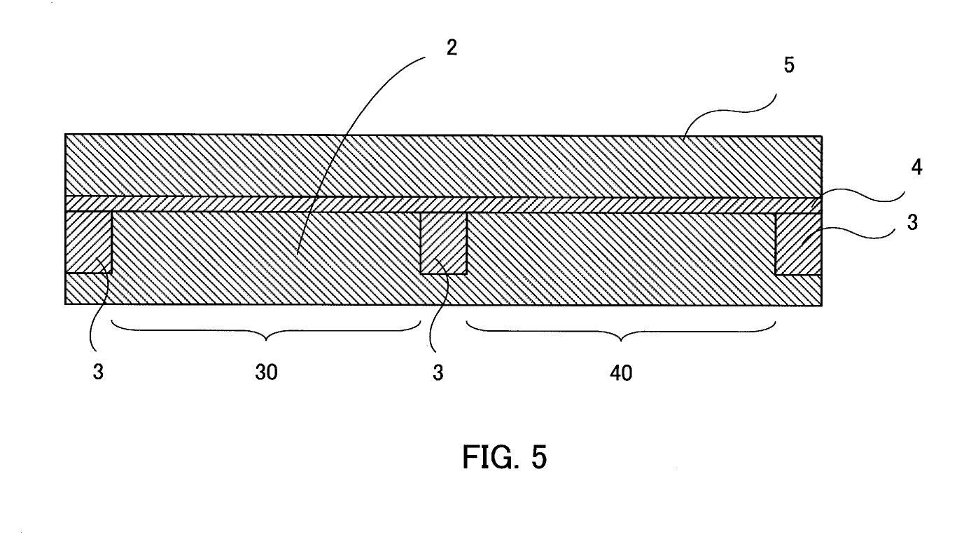

FIG. 5 is an example of a fragmentary sectional view showing the step of forming a poly-Si layer.

Then a gate insulating film 4 with a thickness of about 1.5 nm is formed over the Si substrate 2 by a thermal oxidation method. A poly-Si layer 5 with a thickness of about 120 nm is formed over the gate insulating film 4 by a chemical vapor deposition (CVD) method (step S11).

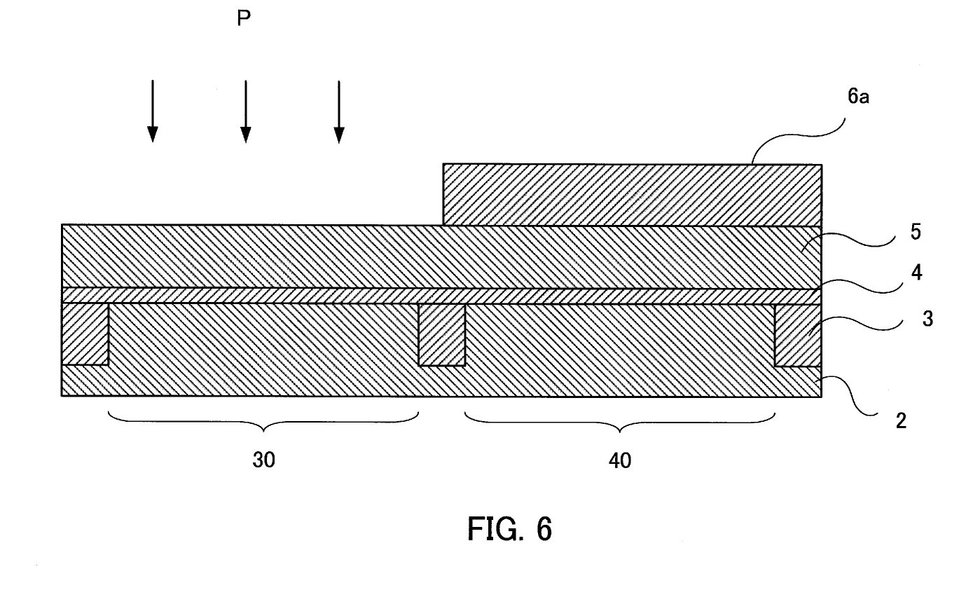

FIG. 6 is an example of a fragmentary sectional view showing the step of implanting impurities.

Then a mask 6a is formed over the poly-Si layer 5 in the pMOS region 40. To implant impurities in the poly-Si layer 5 in the nMOS region 30, phosphorus (P) ions are implanted with a dose of about 1×10¹⁵/cm² at an acceleration energy of about 10 keV (step S12). After ion implantation is performed, activation anneal of impurities contained in the poly-Si layer 5 may be performed.

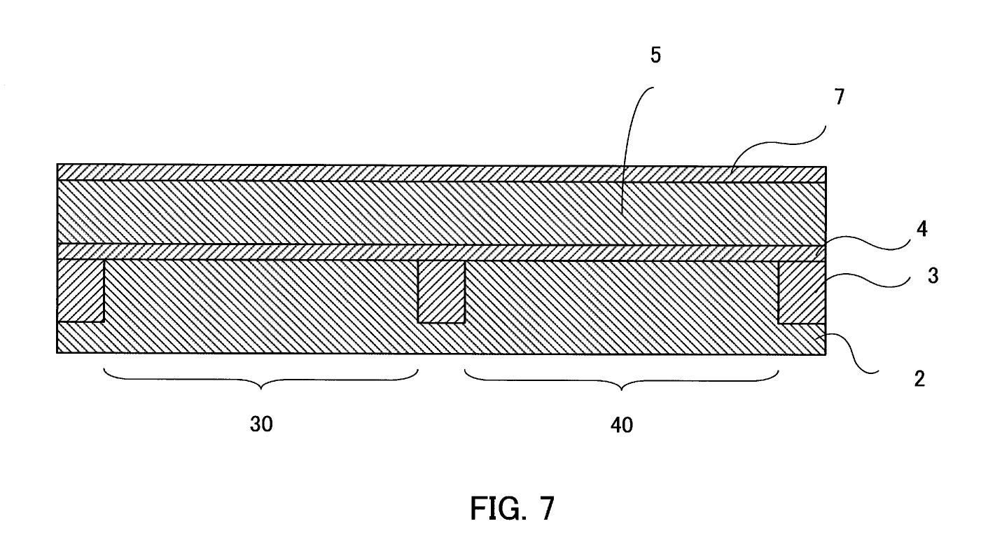

FIG. 7 is an example of a fragmentary sectional view showing the step of forming a hard mask.

After the mask 6a shown in FIG. 6 is removed, a hard mask 7 is formed over the poly-Si layer 5. This hard mask 7 is used for forming the gate electrodes (step S13). The details of this step will be described later.

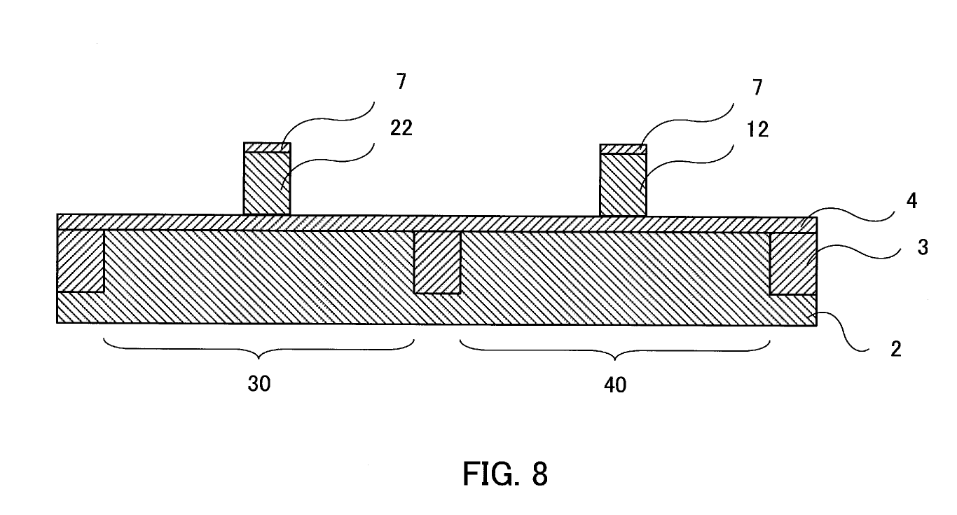

FIG. 8 is an example of a fragmentary sectional view showing the step of forming the gate electrodes.

Then patterning is performed on the hard mask 7 so that it will have the shape of the gate electrodes (not shown). After that, the gate electrodes 22 and 12 are formed in the nMOS region 30 and the pMOS region 40 respectively (step S14). The details of this step will be described later.

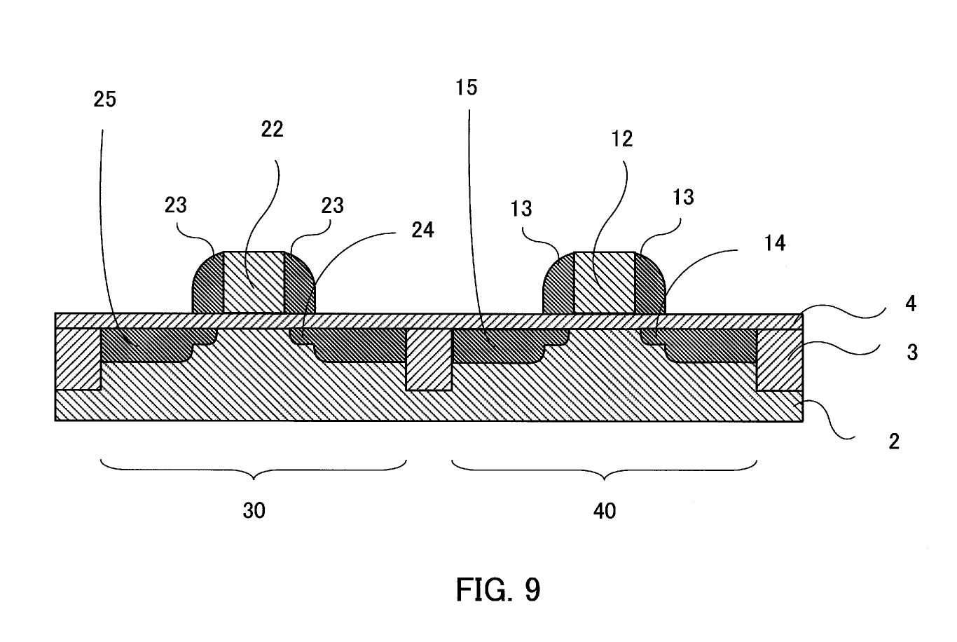

FIG. 9 is an example of a fragmentary sectional view showing the step of forming the side wall insulating films and the source/drain regions.

After the gate electrodes 12 and 22 shown in FIG. 8 are formed, impurities are implanted in the source/drain extension regions 24 in the nMOS region 30 (step S15).

To be concrete, indium (In) ions used as p-type impurities are implanted four times from four directions at an angle of twenty-five degrees and arsenic (As) ions used as n-type impurities are implanted. In addition, impurities are implanted in the source/drain extension regions 14 in the pMOS region 40. To be concrete, As ions used as n-type impurities are implanted four times from four directions at an angle of twenty-five degrees and boron (B) ions used as p-type impurities are implanted.

Then an oxide film with a thickness of about 100 nm is formed by the CVD method at a substrate temperature of about 580° C. (not shown). An etch-back is performed to form the side wall insulating films 13 and 23 (step S16).

In addition, P ions are implanted on both sides of the gate electrode 22 and B ions are implanted on both sides of the gate electrode 12. By doing so, the source/drain regions 15 and 25 are formed (step S17).

Then B ions used as p-type impurities are implanted in the gate electrode 12 (not shown).

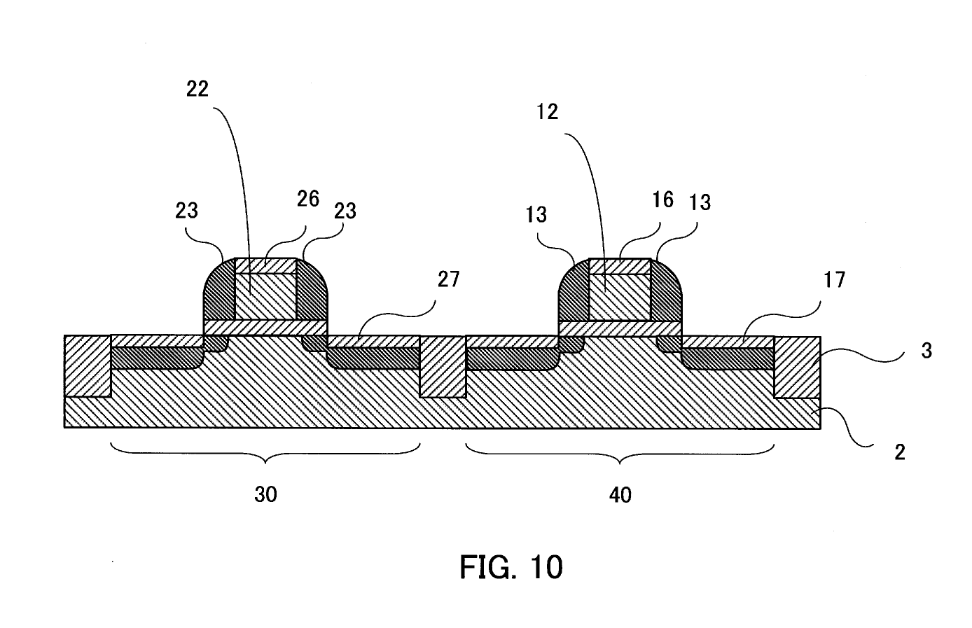

FIG. 10 is an example of a fragmentary sectional view showing the step of forming the silicide films.

After activation anneal is performed, the hard mask 7 over the gate electrodes 12 and 22 shown in FIG. 8 and the gate insulating film 4 over the source/drain regions 15 and 25 shown in FIG. 8 are removed so that the surfaces of the gate electrodes 12 and 22 and the source/drain regions 15 and 25 will get exposed (step S18).

A cobalt (Co) film is formed over the gate electrodes 12 and 22 and the source/drain regions 15 and 25 by sputtering and silicide films 16, 17, 26, and 27 of cobalt silicon (CoSi) with a thickness of about 20 nm are formed by a salicide method (step S19).

The CMOSFET 1a shown in FIG. 2 is fabricated by performing these steps.

The step of forming the hard mask shown in FIG. 7 and the step of forming the gate electrodes shown in FIG. 8 will now be described in detail.

First, second, and third methods can be used for performing the two steps. Descriptions of the first, second, and third methods will be given with the formation of the gate electrode of the MOSFET 10 shown in FIG. 2 as an example.

The first method will be described first.

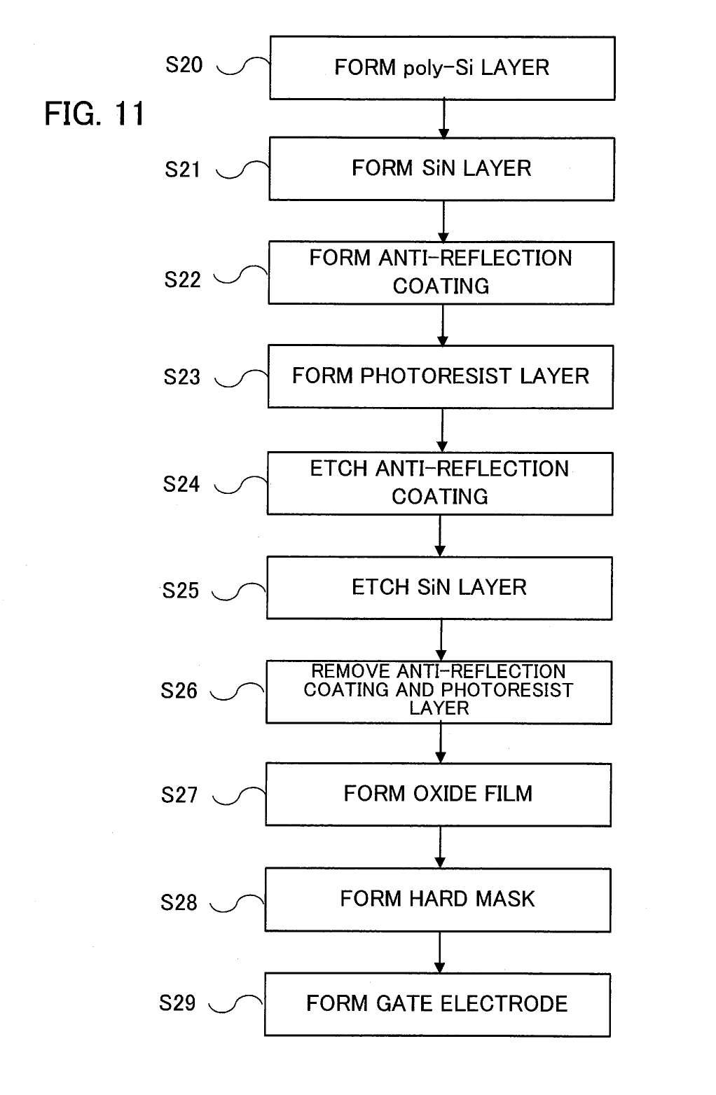

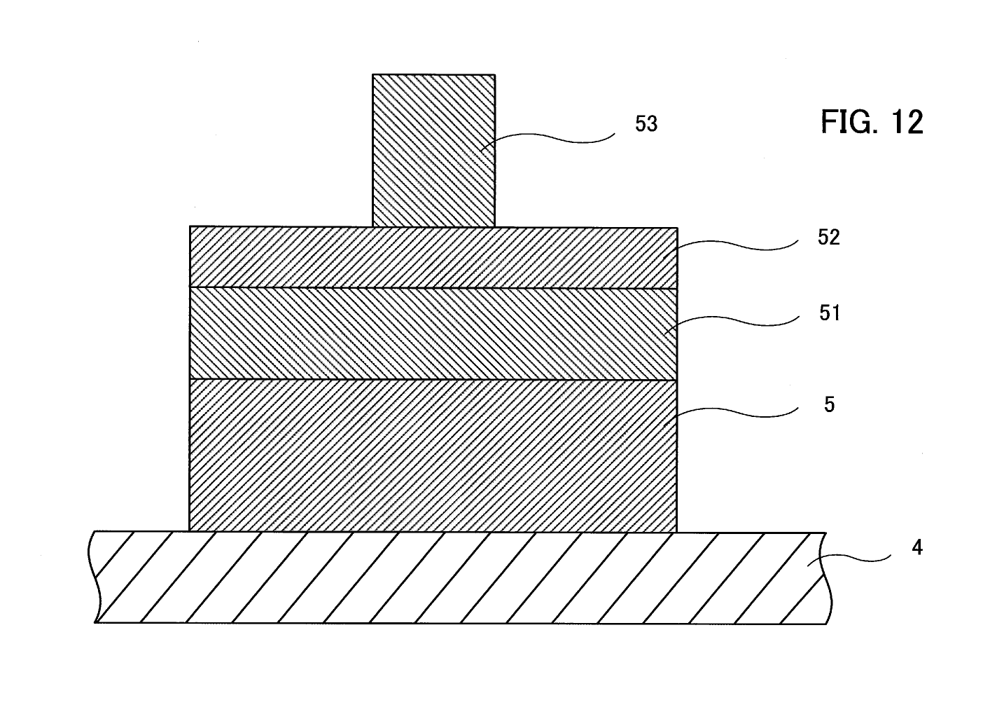

FIG. 11 is an example of a view for describing the principles of the step of forming a gate electrode by the first method. Each of FIGS. 12 through 17 is an example of a fragmentary sectional view showing each step performed for forming a gate electrode by the first method. The principles of the step of forming a gate electrode by the first method shown in FIG. 11 will now be described in detail, together with each step which is performed for forming a gate electrode by the first method and which is shown in FIGS. 12 through 17.

FIG. 12 is an example of a fragmentary sectional view showing the step of forming a photoresist layer.

As shown in FIG. 12, a poly-Si layer 5 with a thickness of, for example, 120 nm is formed first over a gate insulating film 4 (step S20).

Then a SiN layer 51 with a thickness of, for example, 50 nm is formed by a low pressure CVD (LPCVD) method or a plasma CVD method (step S21).

An anti-reflection coating 52 with a thickness of, for example, 80 nm is formed over the SiN layer 51 (step S22).

A photoresist layer 53 is formed over the anti-reflection coating 52 over a portion of the poly-Si layer 5 in which the gate electrode 12 shown in FIG. 8 is to be formed (step S23). The thickness and width of the photoresist layer 53 are set so that it will not, for example, deform or come down during the process. To be concrete, the thickness and width of the photoresist layer 53 are set to 250 nm and 80 nm respectively.

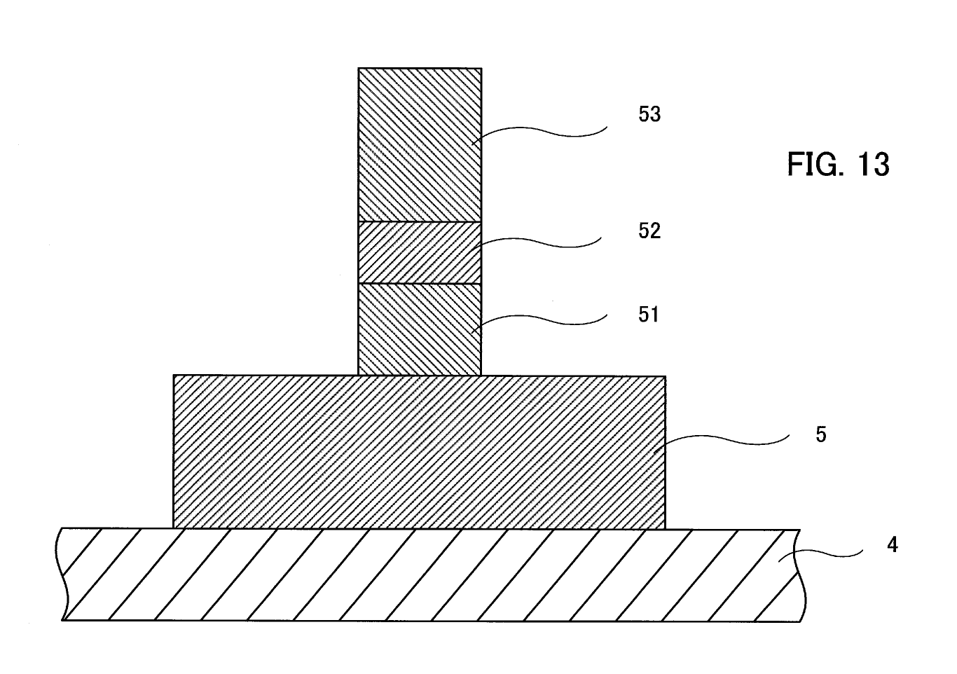

FIG. 13 is an example of a fragmentary sectional view showing an etching step.

As shown in FIG. 13, then the anti-reflection coating 52 is etched by the use of plasma of, for example, mixed gas which contains oxygen (O₂) and tetrafluorocarbon (CF₄) with the photoresist layer 53 as a mask (step S24). The SiN layer 51 is etched by the use of plasma of, for example, fluorocarbon type gas (such as CF₄ or CHF₃) (step S25). The photoresist layer 53, the SiN layer 51, and the anti-reflection coating 52 after the etching are, for example, 60 nm in width.

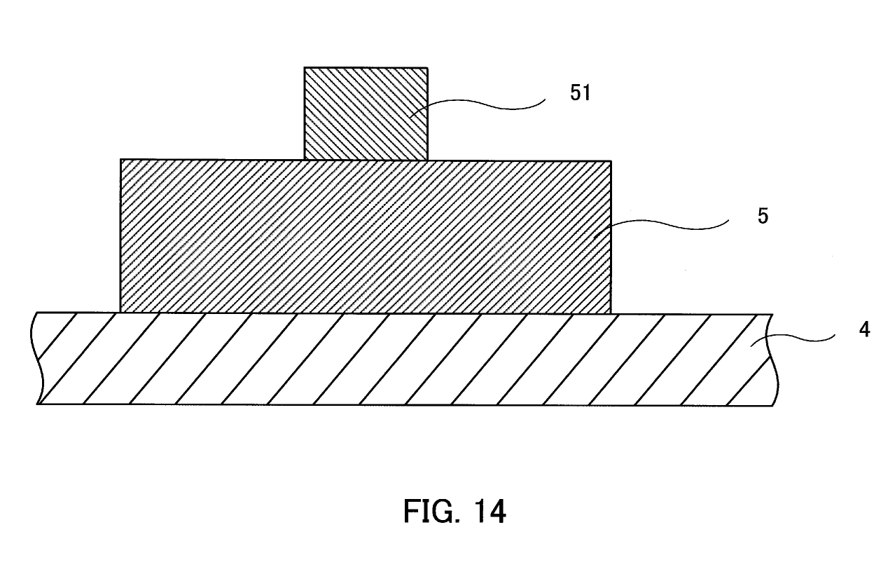

FIG. 14 is an example of a fragmentary sectional view showing the step of removing the anti-reflection coating and the photoresist layer.

Then the anti-reflection coating 52 and the photoresist layer 53 shown in FIG. 13 are removed (step S26) so that the SiN layer 51 will get exposed.

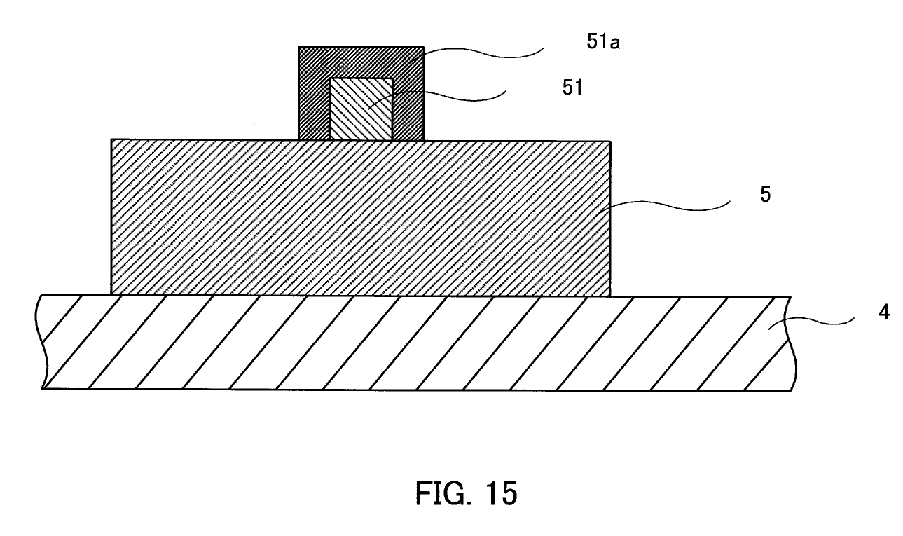

FIG. 15 is an example of a fragmentary sectional view showing the step of forming an oxide film on the surface of the SiN layer.

As shown in FIG. 15, then an oxide film 51a is formed on the surface of the SiN layer 51, for example, by a down flow plasma ashing method by the use of plasma which contains O₂ gas at a substrate temperature of about 250° C. in order to transmute surface portions of the SiN layer 51 (step S27). The oxide film 51a is a SiON film or a SiO₂ film.

The main component of material gas used for forming the oxide film 51a is O₂. By adding a minute amount of CF₄ (<5 weight percentage), however, oxidization is speeded up. By adding nitrogen (N₂) or N₂ and hydrogen (H₂) to the material gas, the number of O₂ radicals in plasma increases and oxidization is speeded up further.

In addition, by controlling the composition of SiN, an oxidization rate can be controlled.

The reason for setting the temperature of the substrate to 250° C. is to prevent the diffusion of impurities implanted in the preceding step. It is desirable that the temperature of the substrate should be set to 400° C. or less.

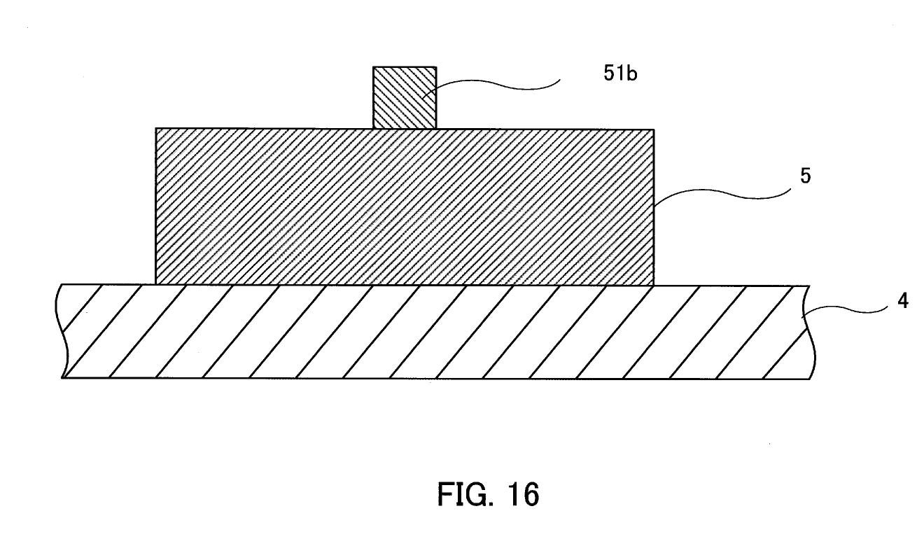

FIG. 16 is an example of a fragmentary sectional view showing the step of forming a hard mask.

Then the oxide film 51a shown in FIG. 15 is selectively removed by performing etching by the use of a dilute solution of HF (0.5 weight percentage, for example). By doing so, a hard mask 51b of SiN with a width of, for example, 30 nm is formed (step S28).

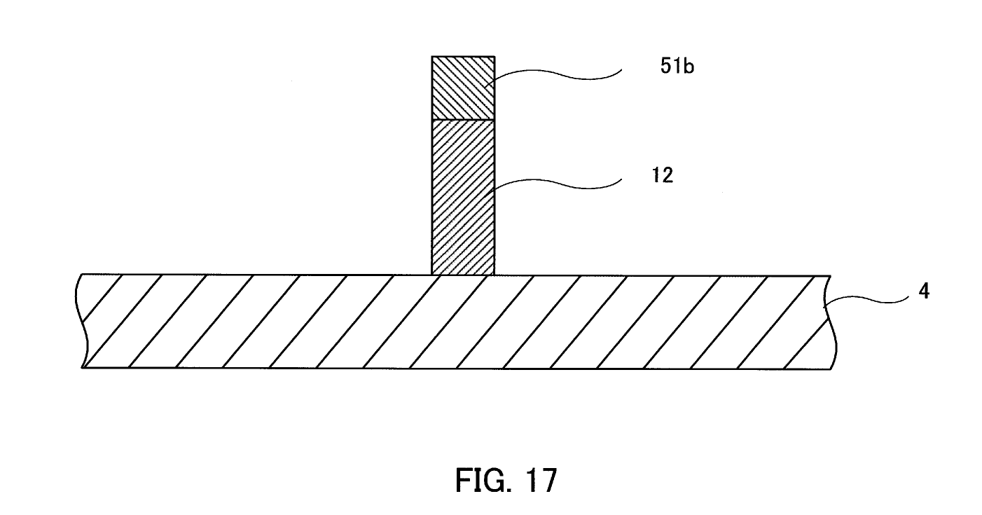

FIG. 17 is an example of a fragmentary sectional view showing the step of forming a gate electrode.

The poly-Si layer 5 is etched by plasma of, for example, hydrogen bromide (HBr) with the hard mask 51b as a mask. By doing so, a gate electrode 12 with a width of, for example, 30 nm is formed (step S29).

If the above method is adopted, the photoresist layer 53 maintains a shape having sufficient mechanical strength and does not deform during the process. As a result, the SiN layer 51 can be etched stably. In addition, a SiON film or a SiO₂ film is formed on the surface of the SiN layer 51 and is removed. By doing so, the SiN layer 51 is reduced. As a result, the minute hard mask 51b of SiN can stably be formed over the poly-Si layer 5. Furthermore, by etching the poly-Si layer 5 with the hard mask 51b as a mask, the minute gate electrode 12 can stably be formed.

The second method will now be described.

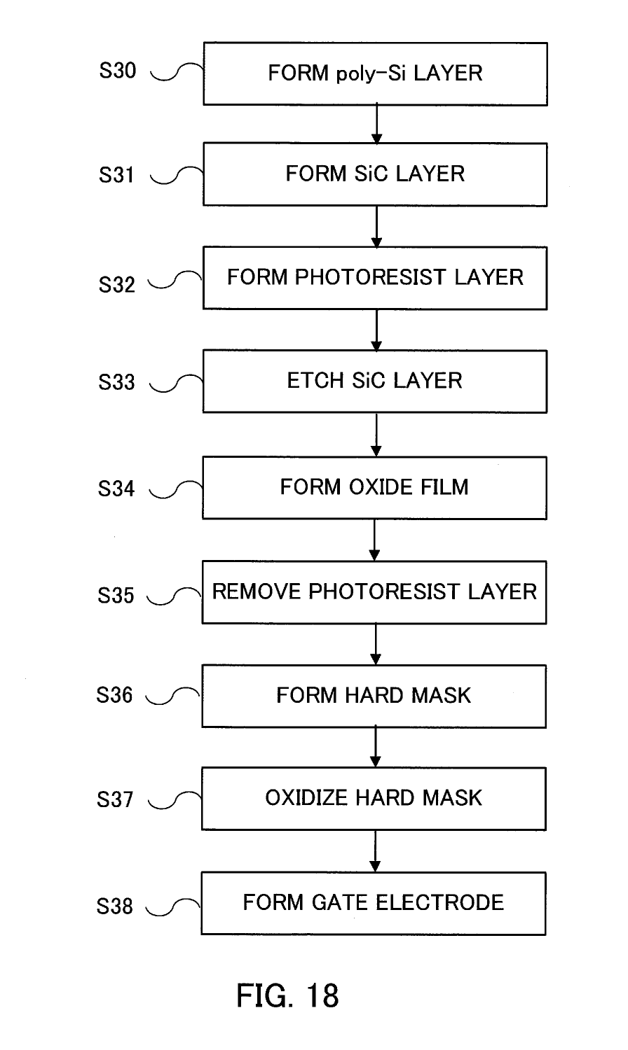

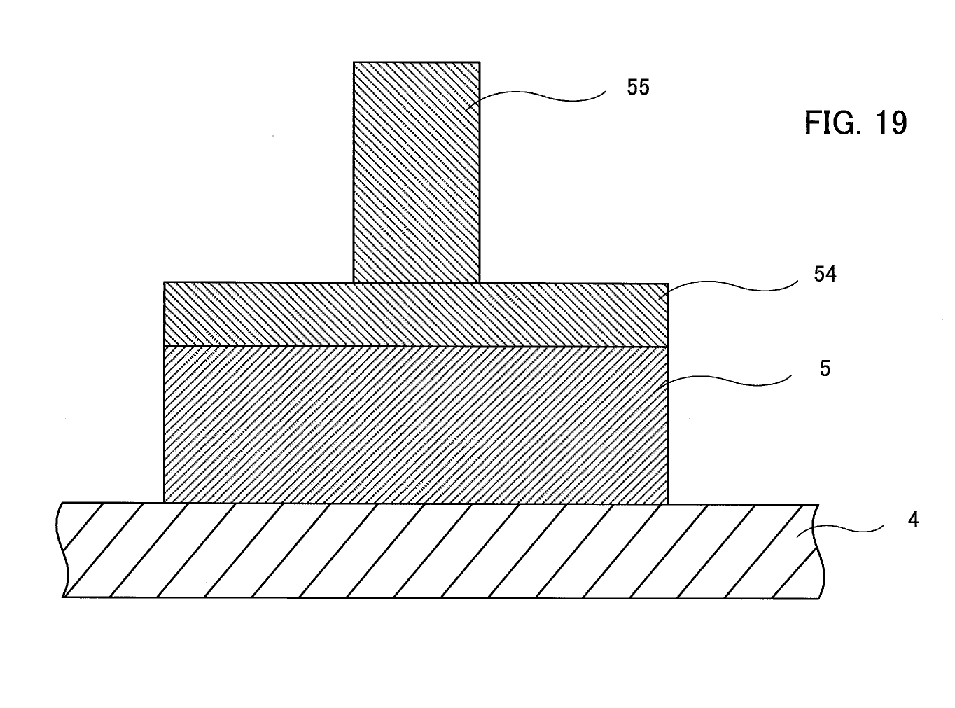

FIG. 18 is an example of a view for describing the principles of the step of forming a gate electrode by the second method. Each of FIGS. 19 through 23 is an example of a fragmentary sectional view showing each step performed for forming a gate electrode by the second method. The principles of the step of forming a gate electrode by the second method shown in FIG. 18 will now be described in detail, together with each step which is performed for forming a gate electrode by the second method and which is shown in FIGS. 19 through 23.

FIG. 19 is an example of a fragmentary sectional view showing the step of forming a photoresist layer.

As shown in FIG. 19, a poly-Si layer 5 with a thickness of, for example, 120 nm is formed first over a gate insulating film 4 (step S30).

Then a silicon carbide (SiC) layer 54 with a thickness of, for example, 100 nm is formed by the plasma CVD method or a spin coat method (step S31).

A photoresist layer 55 is formed over the SiC layer 54 over a portion of the poly-Si layer 5 in which the gate electrode 12 shown in FIG. 8 is to be formed (step S32). The thickness and width of the photoresist layer 55 are set so that it will not, for example, deform or come down during the process. To be concrete, the thickness and width of the photoresist layer 55 are set to 300 nm and 80 nm respectively.

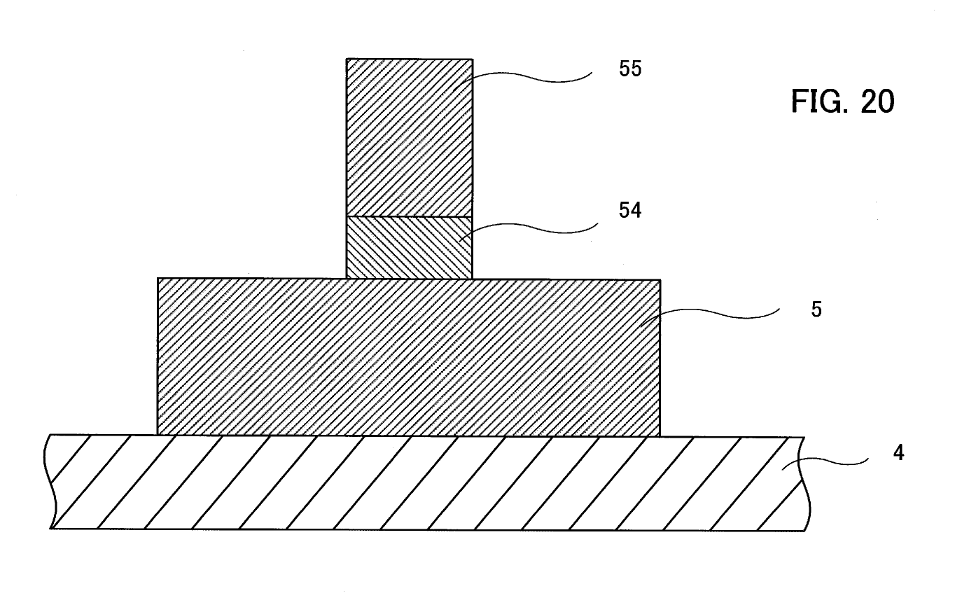

FIG. 20 is an example of a fragmentary sectional view showing an etching step.

As shown in FIG. 20, then the SiC layer 54 is etched by the use of plasma of, for example, gas (such as CF₄ or SF₆) which contains fluorine or mixed gas which contains O₂ and hydrofluorocarbon (CH₂F₂) with the photoresist layer 55 as a mask (step S33).

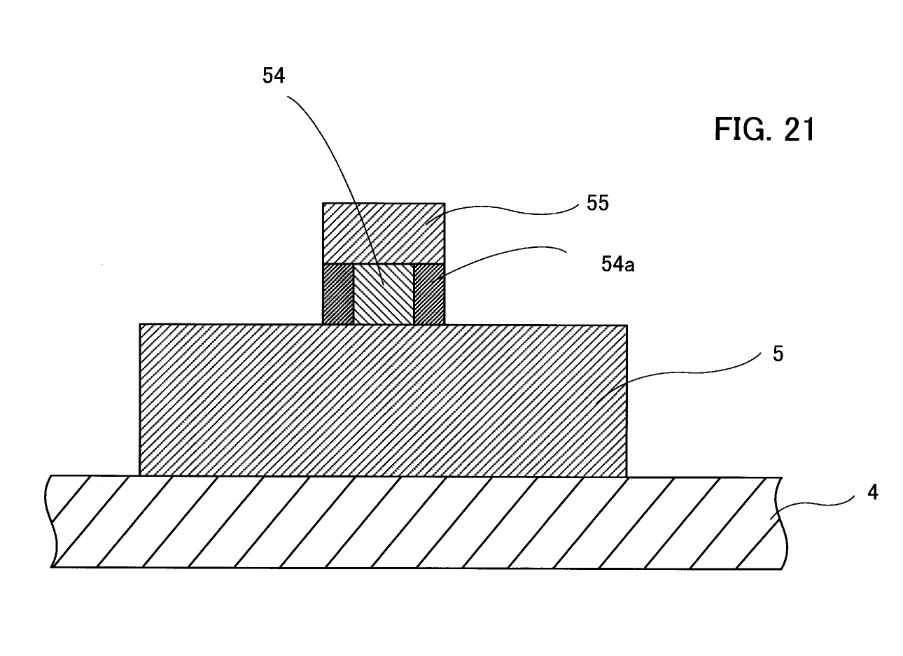

FIG. 21 is an example of a fragmentary sectional view showing the step of forming an oxide film on the sides of the SiC layer.

As shown in FIG. 21, then an oxide film 54a is formed on the sides of the SiC layer 54, for example, by using the down flow plasma ashing method by the use of plasma which contains O₂ gas at a substrate temperature of about 250° C. in order to transmute side portions of the SiC layer 54 (step S34). This is in-situ treatment. The reason for setting the temperature of the substrate to 250° C. is to prevent the diffusion of impurities implanted in the preceding step.

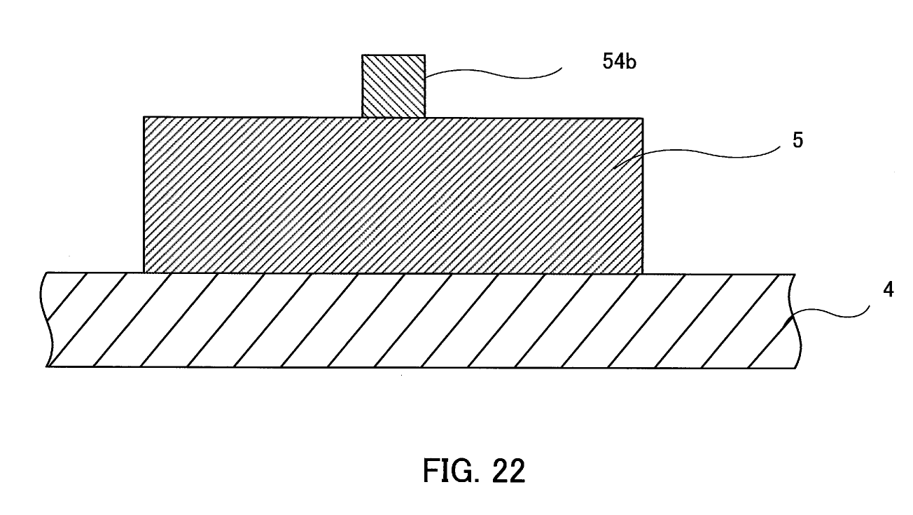

FIG. 22 is an example of a fragmentary sectional view showing the step of forming a hard mask.

After that, the photoresist layer 55 shown in FIG. 21 is removed (step S35) and the oxide film 54a is selectively removed by performing etching by the use of a dilute solution of HF (0.5 weight percentage, for example). By doing so, a hard mask 54b of SiC with a width of, for example, 20 nm is formed (step S36).

The entire hard mask 54b may be oxidized to form SiOC (silicon oxide film which contains carbon) or SiO₂. SiOC or SiO₂ formed in this way can be used as the hard mask 54b (step S37). By using the hard mask 54b of SiOC or SiO₂, a rate at which the hard mask 54b is etched in the next step can be reduced. As a result, a decrease in the thickness of the hard mask 54b can be suppressed. In addition, the hard mask 54b can easily be removed by the use of, for example, a dilute solution of HF which is commonly used in posttreatment after the formation of a gate electrode.

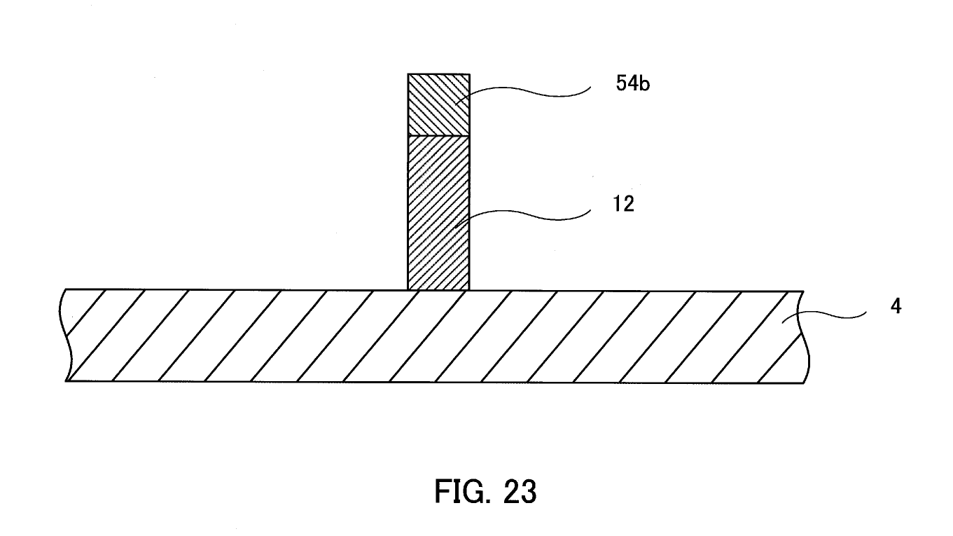

FIG. 23 is an example of a fragmentary sectional view showing the step of forming a gate electrode.

The poly-Si layer 5 is etched by the use of plasma of, for example, HBr with the hard mask 54b as a mask. By doing so, a gate electrode 12 with a width of, for example, 20 nm is formed (step S38).

If the above method is adopted, the photoresist layer 55 maintains a shape having sufficient mechanical strength and does not deform during the process. As a result, the SiC layer 54 can be etched stably. In addition, in-situ plasma treatment is performed in a state in which the photoresist layer 55 is formed over the SiC layer 54, so only the sides of the SiC layer 54 are oxidized. By removing the oxide film 54a, the SiC layer 54 is reduced. As a result, the hard mask 54b with predetermined thickness can be ensured and the corners of the top of the hard mask 54b do not round easily. Accordingly, by etching the poly-Si layer 5 with the hard mask 54b as a mask, the minute gate electrode 12 can be formed stably.

In the above descriptions, the temperature of the substrate is set to, for example, 250° C. when the oxide film 54a is formed on the sides of the SiC layer 54. The surface of SiC is easily oxidized at a temperature of 100 to 200° C., so process temperature can be lowered. In addition, by controlling the composition of the SiC layer 54, the SiC layer 54 has the function of preventing the reflection of exposure light. In this case, the step of forming the anti-reflection coating 52 shown in FIG. 12 can be omitted.

The third method will now be described.

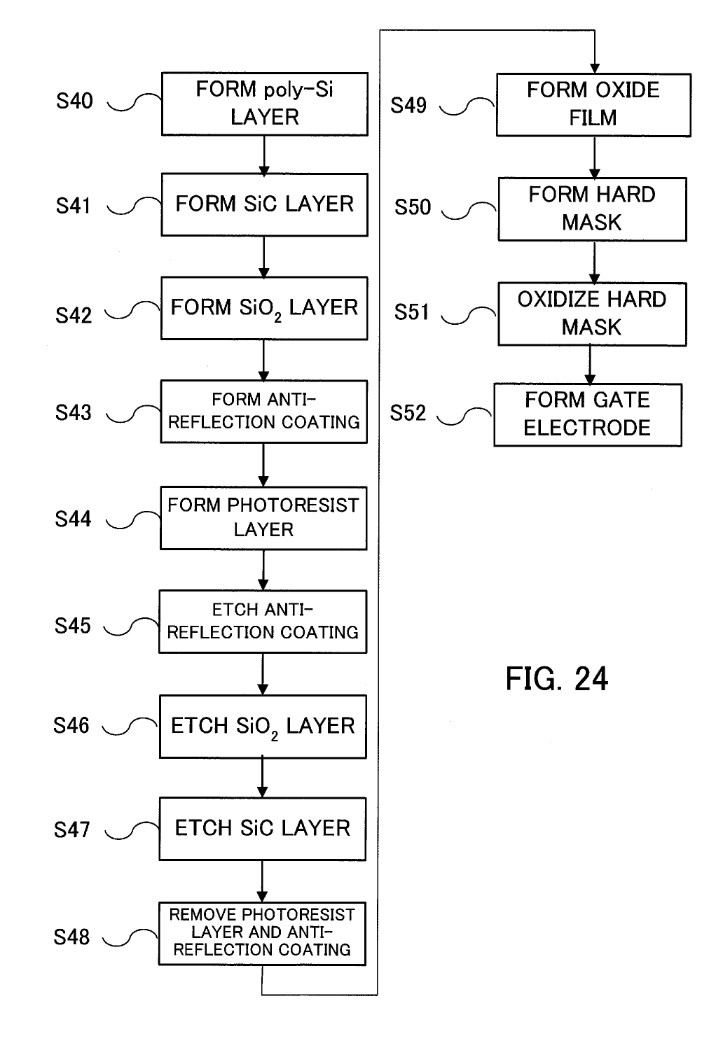

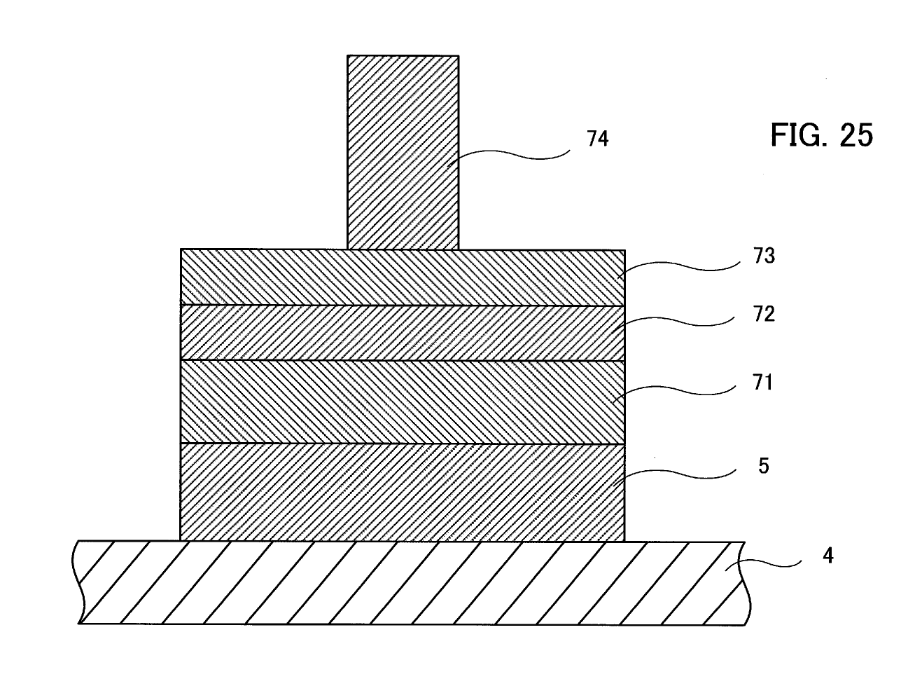

FIG. 24 is an example of a view for describing the principles of the step of forming a gate electrode by the third method. Each of FIGS. 25 through 30 is an example of a fragmentary sectional view showing each step performed for forming a gate electrode by the third method. The principles of the step of forming a gate electrode by the third method shown in FIG. 24 will now be described in detail, together with each step which is performed for forming a gate electrode by the third method and which is shown in FIGS. 25 through 30.

FIG. 25 is an example of a fragmentary sectional view showing the step of forming a photoresist layer.

As shown in FIG. 25, a poly-Si layer 5 with a thickness of, for example, 120 nm is formed first over a gate insulating film 4 (step S40).

Then a SiC layer 71 with a thickness of, for example, 100 nm is formed by the plasma CVD method or the spin coat method (step S41).

Then a SiO₂ layer 72 with a thickness of, for example, 30 nm is formed over the SiC layer 71 by the LPCVD method (step S42).

Then an anti-reflection coating 73 with a thickness of, for example, 80 nm is formed over the SiO₂ layer 72 (step S43).

A photoresist layer 74 is formed over the anti-reflection coating 73 over a portion of the poly-Si layer 5 in which the gate electrode 12 shown in FIG. 8 is to be formed (step S44). The thickness and width of the photoresist layer 74 are set so that it will not, for example, deform or come down during the process. To be concrete, the thickness and width of the photoresist layer 74 are set to 250 nm and 80 nm respectively.

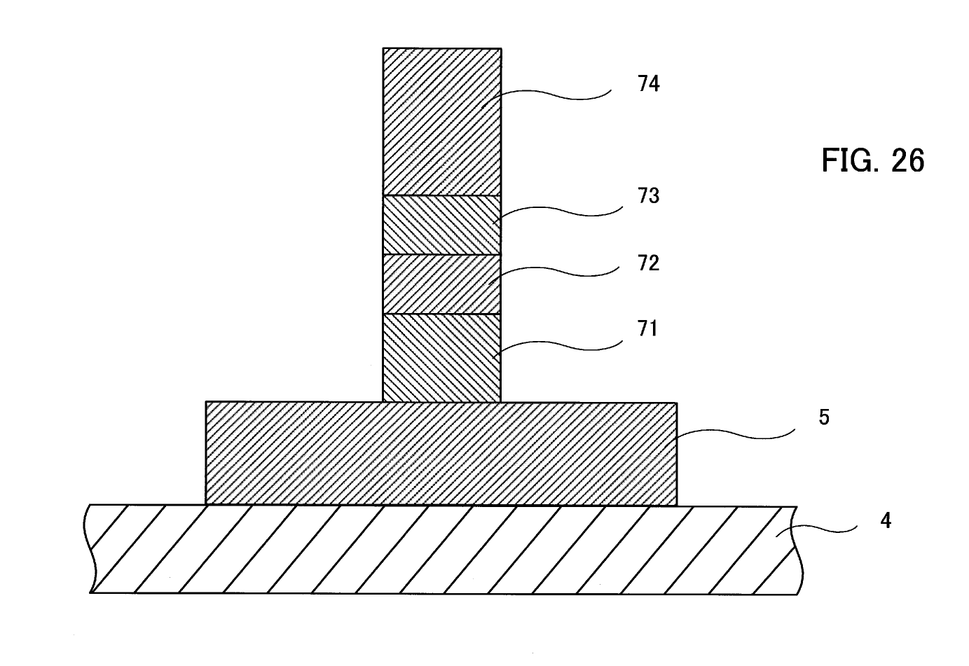

FIG. 26 is an example of a fragmentary sectional view showing an etching step.

As shown in FIG. 26, then the anti-reflection coating 73 is etched by the use of plasma of, for example, mixed gas which contains O₂ and CF₄ with the photoresist layer 74 as a mask (step S45). The SiO₂ layer 72 is etched by the use of plasma of, for example, gas (such as CF₄) which contains fluorine (step S46).

Then the SiC layer 71 is etched by the use of plasma of, for example, gas (such as CF₄ or SF₆) which contains fluorine or mixed gas which contains O₂ and CH₂F₂ (step S47).

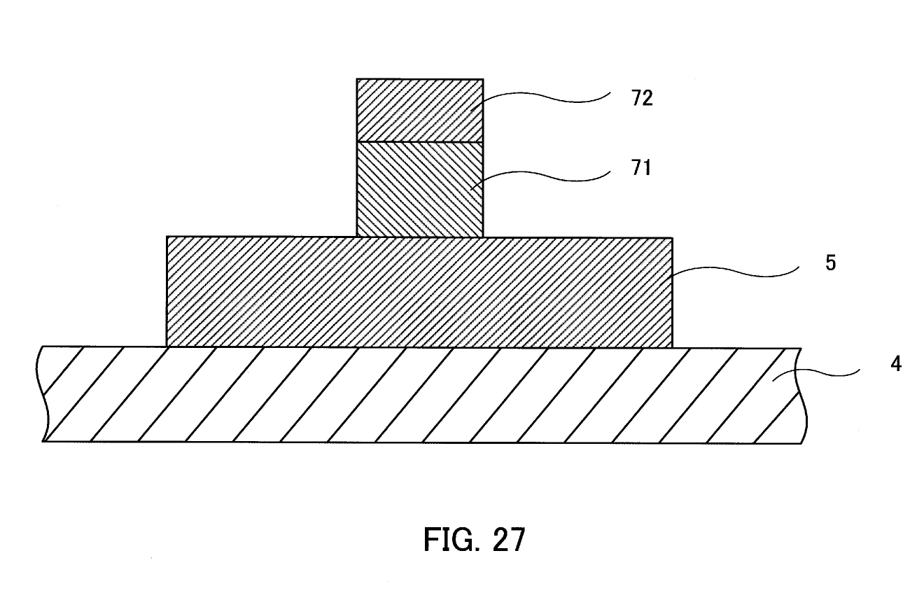

FIG. 27 is an example of a fragmentary sectional view showing the step of removing the photoresist layer and the anti-reflection coating.

The photoresist layer 74 and the anti-reflection coating 73 shown in FIG. 26 are removed (step S48) so that the SiO₂ layer 72 will get exposed.

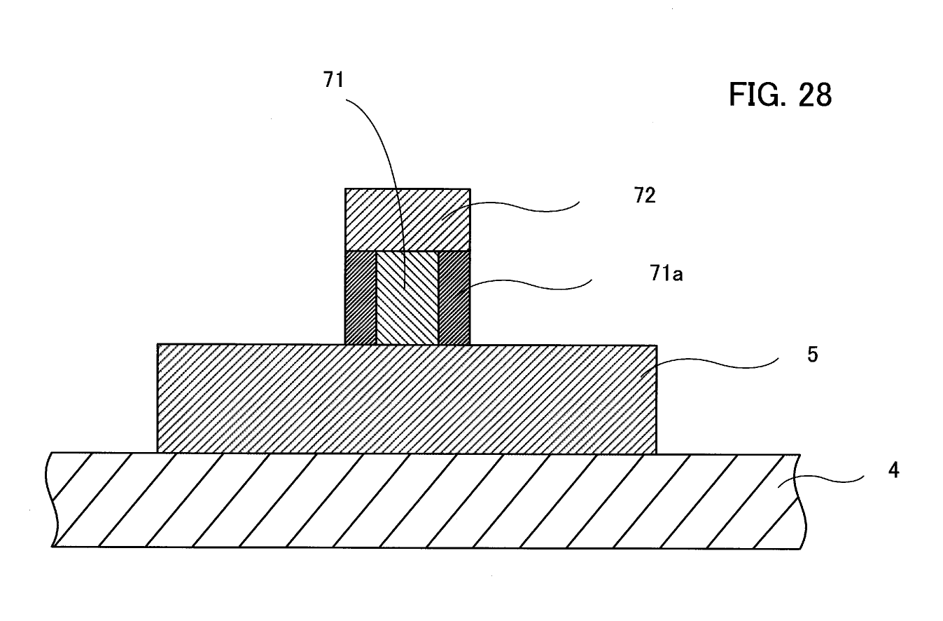

FIG. 28 is an example of a fragmentary sectional view showing the step of forming an oxide film on the sides of the SiC layer.

As shown in FIG. 28, then an oxide film 71a is formed on the sides of the SiC layer 71, for example, by using the down flow plasma ashing method at a substrate temperature of about 250° C. or by performing in-situ treatment (at a temperature of about several tens of degrees) by the use of plasma which contains O₂ gas in order to transmute side portions of the SiC layer 71 (step S49). The reason for setting the temperature of the substrate to 250° C. is to prevent the diffusion of impurities implanted in the preceding step.

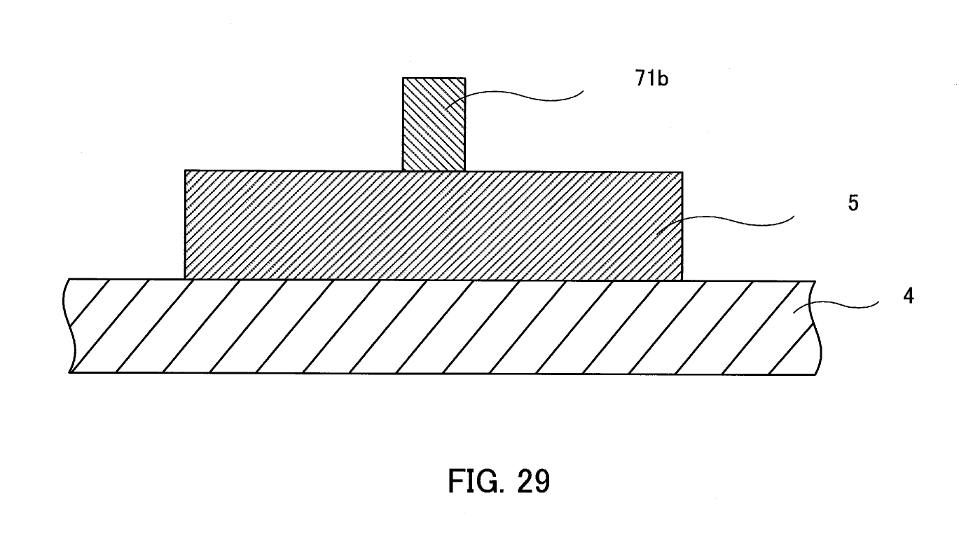

FIG. 29 is an example of a fragmentary sectional view showing the step of forming a hard mask.

After that, the SiO₂ layer 72 and the oxide film 71a shown in FIG. 28 are selectively removed by performing etching by the use of a dilute solution of HF (0.5 weight percentage, for example). By doing so, a hard mask 71b of SiC with a width of, for example, 20 nm is formed (step S50).

The entire hard mask 71b may be oxidized to form SiOC or SiO₂. SiOC or SiO₂ formed in this way can be used as the hard mask 71b (step S51). By using the hard mask 71b of SiOC or SiO₂, a rate at which the hard mask 71b is etched in the next step can be reduced. As a result, a decrease in the thickness of the hard mask 71b can be suppressed. In addition, the hard mask 71b can easily be removed by the use of, for example, a dilute solution of HF which is commonly used in posttreatment after the formation of a gate electrode.

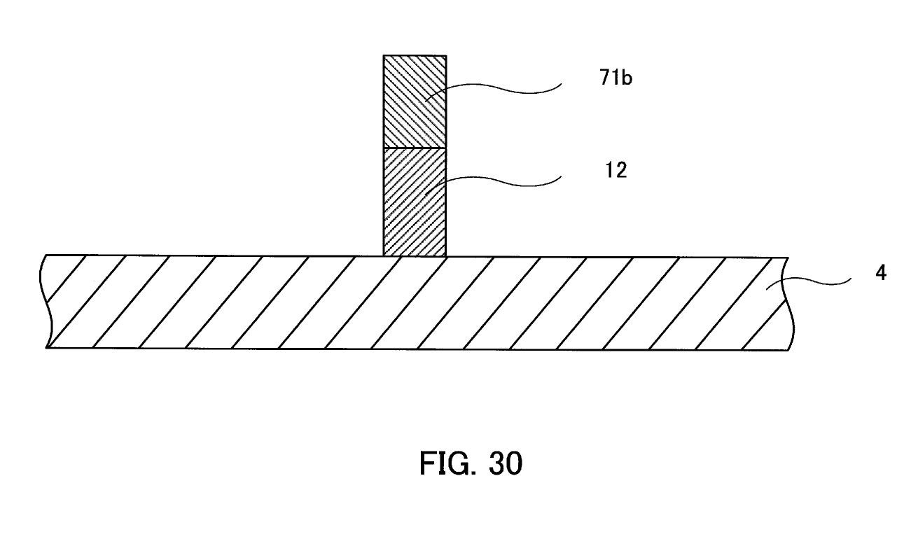

FIG. 30 is an example of a fragmentary sectional view showing the step of forming a gate electrode.

The poly-Si layer 5 is etched by the use of plasma of, for example, HBr with the hard mask 71b as a mask. By doing so, a gate electrode 12 with a width of, for example, 20 nm is formed (step S52).

If the above method is adopted, the photoresist layer 74 maintains a shape having sufficient mechanical strength and does not deform during the process. As a result, the SiC layer 71 can be etched stably. In addition, the SiO₂ layer 72 is formed in advance over the SiC layer 71. Accordingly, the thickness of the SiO₂ layer 72 does not decrease when the oxide film 71a is formed on the sides of the SiC layer 71. This widens a margin for a process condition.

Furthermore, in-situ plasma treatment is performed in a state in which the SiO₂ layer 72 is formed over the SiC layer 71. Therefore, the top of the SiC layer 71 is not etched and only the sides of the SiC layer 71 are oxidized. By removing the oxide film 71a, the SiC layer 71 is reduced. As a result, the hard mask 71b with predetermined thickness can be ensured and the corners of the top of the hard mask 71b do not round easily. Accordingly, by etching the poly-Si layer 5 with the hard mask 71b as a mask, the minute gate electrode 12 can be formed stably.

With the second and third methods, a SiOC layer may be formed in place of the SiC layer 71. The above first, second, and third methods can also be applied to the step of forming the gate electrode of the MOSFET 20 shown in FIG. 2.

A second embodiment of the present invention will now be described.

The differences between the CMOSFET according to the first embodiment of the present invention and a CMOSFET according to a second embodiment of the present invention and the differences in fabrication method between the CMOSFET according to the first embodiment of the present invention and a CMOSFET according to a second embodiment of the present invention will mainly be described. Components of a CMOSFET according to a second embodiment of the present invention that are the same as those shown in FIG. 2 are marked with the same symbols and detailed descriptions of them will be omitted.

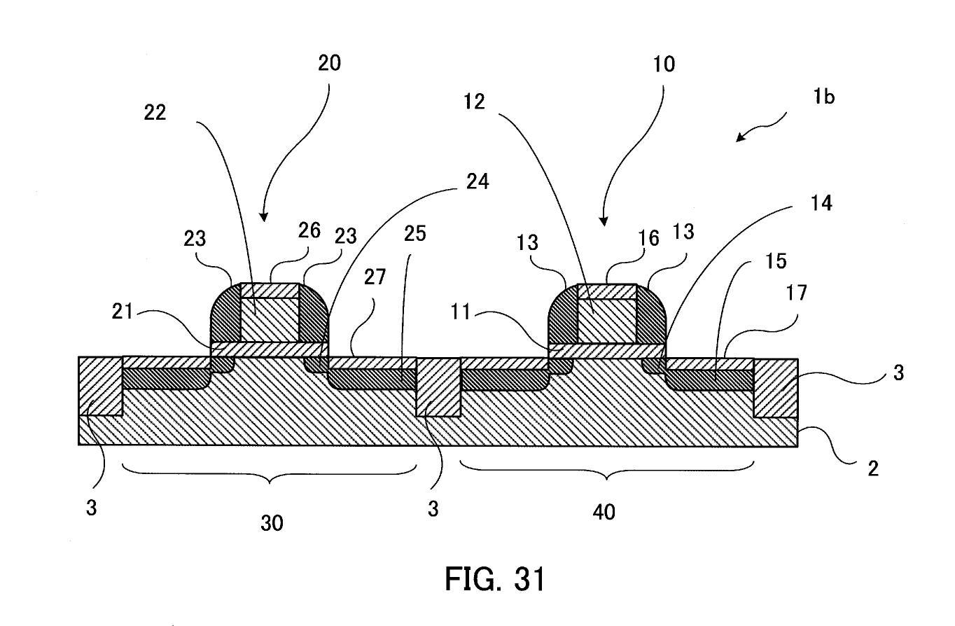

FIG. 31 is an example of a fragmentary sectional view of a CMOSFET according to a second embodiment of the present invention.

A CMOSFET 1b according to a second embodiment of the present invention shown in FIG. 31 differs from the CMOSFET 1a according to the first embodiment of the present invention shown in FIG. 2 in that boron is implanted in a pMOS region 40 as impurities. The other components are the same as those shown in FIG. 2.

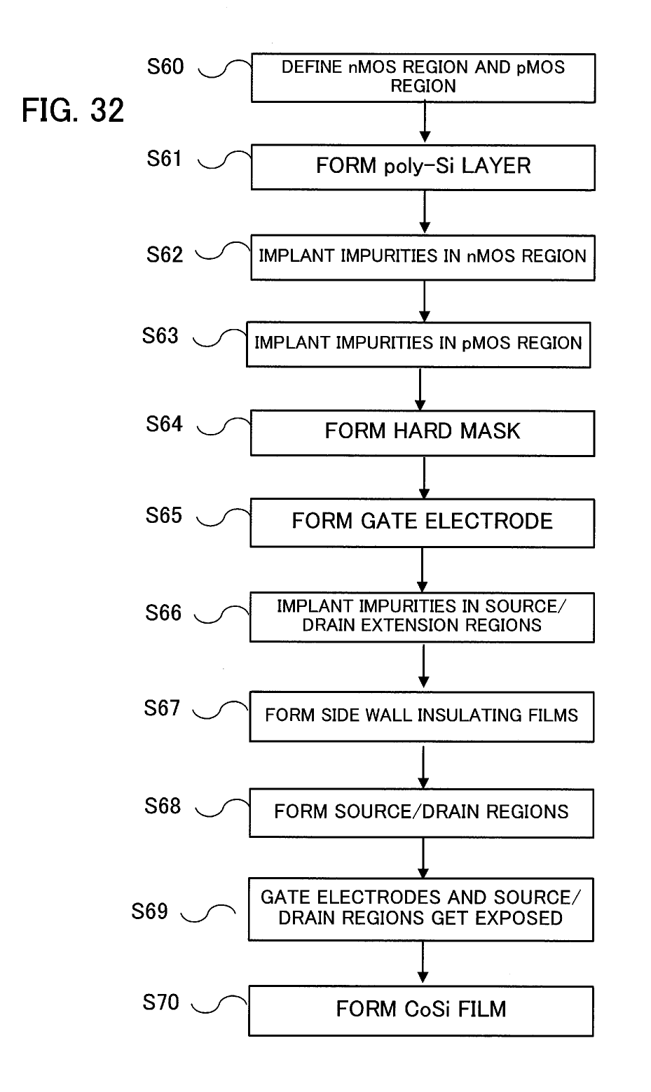

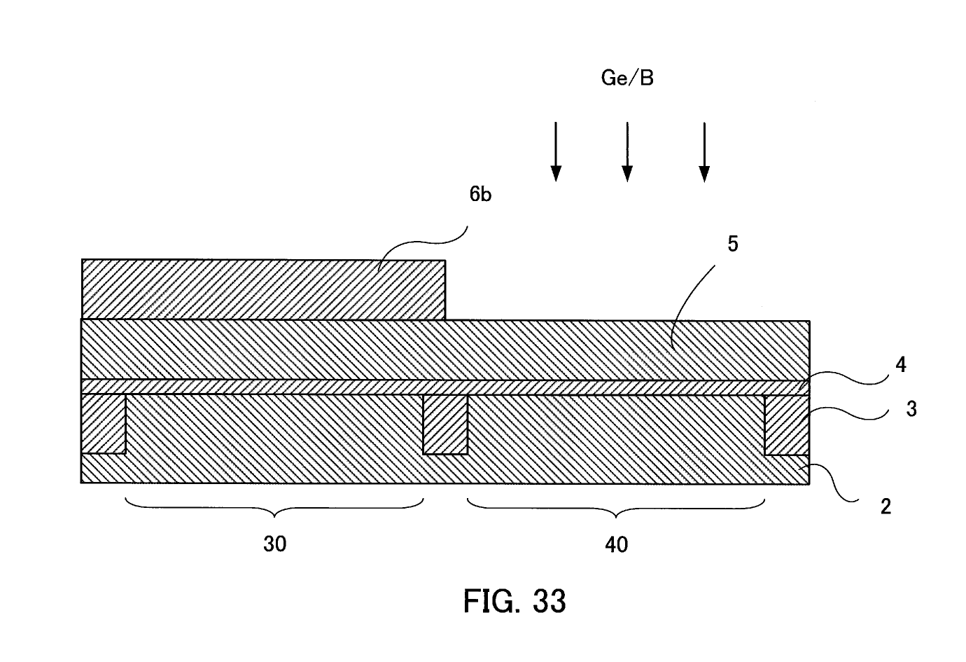

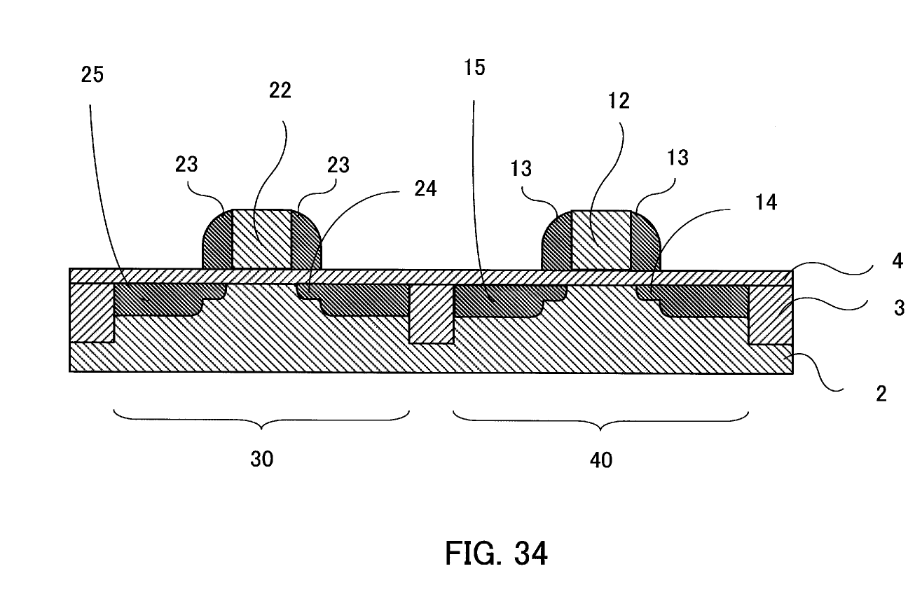

FIG. 32 is an example of a view for describing the principles of fabricating the CMOSFET according to the second embodiment of the present invention. Each of FIGS. 33 and 34 is an example of a fragmentary sectional view showing each step performed for fabricating the CMOSFET according to the second embodiment of the present invention.

The principles of fabricating the CMOSFET according to the second embodiment of the present invention shown in FIG. 32 will now be described in detail, together with each step which is performed for fabricating the CMOSFET according to the second embodiment of the present invention and which is shown in FIGS. 33 and 34.

Steps S60 through S62 are the same as steps S10 through S12, respectively, shown in FIG. 3, so their views will be omitted. In addition, steps S64 through S67 are the same as steps S13 through S16, respectively, shown in FIG. 3, so their views will be omitted. Furthermore, steps S69 and S70 are the same as steps S18 and S19, respectively, shown in FIG. 3, so their views will be omitted.

To isolate one element from the other element, STIs 3 are formed first in a Si substrate 2 and an nMOS region 30 and the pMOS region 40 are defined (step S60). After that, a gate insulating film 4 is formed over the Si substrate 2 and a poly-Si layer 5 is formed over the gate insulating film 4 (step S61). Then impurities are implanted in the poly-Si layer 5 in the nMOS region 30 (step S62).

FIG. 33 is an example of a fragmentary sectional view showing the step of implanting impurities.

A mask 6b is formed so that impurities will be implanted in the pMOS region 40. Germanium (G) is implanted with a dose of 1×10¹⁵/cm² at an acceleration energy of 20 keV to perform pre-amorphization. Then boron ions are implanted with a dose of 1×10¹⁵/cm² at an acceleration energy of 5 keV (step S63).

Then a hard mask 7 used for forming gate electrodes is formed over the poly-Si layer 5 (step S64). Then patterning is performed on the hard mask 7 so that it will have the shape of the gate electrodes. After that, gate electrodes 22 and 12 are formed in the nMOS region 30 and the pMOS region 40 respectively (step S65). Then impurities are implanted in source/drain extension regions 14 of the pMOS region 40 and source/drain extension regions 24 of the nMOS region 30 (step S66). After that, side wall insulating films 13 and 23 are formed on the sides of the gate electrodes 12 and 22 respectively (step S67).

FIG. 34 is an example of a fragmentary sectional view showing the step of forming source/drain regions.

P ions are implanted on both sides of the gate electrode 22 and B ions are implanted on both sides of the gate electrode 12. By doing so, source/drain regions 15 and 25 are formed (step S68).

After activation anneal is performed, the hard mask 7 over the gate electrodes 12 and 22 and the gate insulating film 4 over the source/drain regions 15 and 25 are removed so that the surfaces of the gate electrodes 12 and 22 and the source/drain regions 15 and 25 will get exposed (step S69). A Co film is formed over the gate electrodes 12 and 22 and the source/drain regions 15 and 25 and silicide films 16, 26, 17, and 27 of CoSi are formed over the gate electrodes 12 and 22 and the source/drain regions 15 and 25, respectively, by the salicide method (step S70).

The CMOSFET 1b shown in FIG. 31 is obtained by performing these steps.

As a result, the CMOSFET 1b according to the second embodiment of the present invention shown in FIG. 31 can be fabricated.

The above first, second, and third methods can also be applied to this method for fabricating the CMOSFET 1b and the same effects are obtained.

The semiconductor device fabrication method according to the present invention has been described on the basis of the flow and the embodiments shown. However, the present invention is not limited to these embodiments. Each member can be replaced with any member having the same function. In addition, any other member or step may be added to the present invention. Furthermore, any two or more of the above embodiments may be combined.

In addition, the above first, second, and third methods can also be applied easily to a case where the above salicide method is not used.

For example, if a gate electrode has a three-layer structure including a SiN layer, a tungsten silicide (WSi) layer, and a poly-Si layer, then the above first method can be applied. In this case, there is no need to change the first method. If the above second or third method is applied, a SiN layer should be formed before the formation of a SiC layer. That is to say, the above second or third method can be applied easily by adopting a gate electrode having a four-layer structure including a SiC layer, a SiN layer, a WSi layer, and a poly-Si layer.

In addition, the above WSi layer can be replaced with a tungsten (W) layer and a tungsten nitride (WN) layer or a W layer and a titanium nitride (TiN) layer. In this case, the WN layer or the TiN layer is a barrier layer between the W layer and the poly-Si layer.

If a metal gate electrode is used as a gate electrode, a single-layer poly-Si layer should be replaced with, for example, a two-layer structure including a poly-Si layer and a metal layer. By doing so, the above first, second, and third methods can be applied. For example, titanium (Ti), zirconium (Zr), W, tantalum (Ta), nickel (Ni), molybdenum (Mo), or one of these metals in which N₂ is implanted is used for forming the metal layer.

Furthermore, SiO₂, SiON, SiN, hafnium oxide (HfO₂), or hafnium silicon nitride (HfSiN) may be used as a gate insulating film. In addition, a memory bit line having, for example, a laminated structure including WSi and Si or W and TiN should be used.

The above descriptions have been given with the formation of a gate electrode as an example. However, the above first, second, and third methods can also be applied to the formation of various patterns, such as wirings, of a semiconductor device.

According to the present invention, a first mask layer is formed over a conductive layer. Then a second mask layer is formed over the first mask layer. After pattering is performed on the second mask layer, patterning is performed on the first mask layer by the use of the second mask layer. Surface portions of the first mask layer are transmuted and removed. As a result, the first mask layer is reduced. Patterning is performed on the conductive layer by the use of the reduced first mask layer.

As a result, a semiconductor device fabrication method by which a desired pattern can be formed can be realized.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A method for fabricating a semiconductor device, the method comprising:
forming a first mask layer over a conductive layer;
forming a second mask layer over the first mask layer;
performing patterning on the second mask layer;
performing patterning on the first mask layer by the use of the second mask layer patterned;
transmuting exposed surface portions of the first mask layer;
reducing the first mask layer by removing the transmuted surface portions; and
performing patterning on the conductive layer by the use of the reduced first mask layer.

2. The method according to claim 1, wherein in transmuting the exposed surface portions of the first mask layer, the exposed surface portions are oxidized to form an oxide film.

3. The method according to claim 1, further comprising removing the second mask layer patterned between the patterning of the first mask layer by the use of the second mask layer patterned and the transmuting of the exposed surface portions of the first mask layer.

4. The method according to claim 1, wherein in the patterning of the second mask layer:
the second mask layer is formed by the use of photoresist; and
dimensions of the patterning of the second mask layer are set such that a shape of the second mask layer patterned can be kept until the patterning of the first mask layer by the use of the second mask layer patterned.

5. The method according to claim 1, further comprising forming an anti-reflection coating over the first mask layer after forming the first mask layer over the conductive layer, wherein in forming the second mask layer over the first mask layer, the second mask layer is formed over the anti-reflection coating by the use of photoresist.

6. The method according to claim 1, further comprising forming over the first mask layer a layer of a material which can be removed together with the transmuted surface portions at the time of transmuting and removing the surface portions of the first mask layer after forming the first mask layer over the conductive layer, wherein in forming the second mask layer over the first mask layer, the second mask layer is formed over the layer.

7. The method according to claim 6, wherein:
after the second mask layer is formed over the layer, patterning is performed on the second mask layer and patterning is performed on the layer and the first mask layer by the use of the second mask layer patterned;
in transmuting the exposed surface portions of the first mask layer after the patterning of the layer and the first mask layer, exposed side surface portions of the first mask layer over which the layer patterned is formed are transmuted; and
in reducing the first mask layer by removing the transmuted surface portions, the first mask layer is reduced by removing the layer formed over the first mask layer together with the surface portions.

8. The method according to claim 7, further comprising forming an anti-reflection coating over the layer after forming the layer, wherein in forming the second mask layer over the first mask layer, the second mask layer is formed over the anti-reflection coating by the use of photoresist.

9. The method according to claim 1, wherein the first mask layer is formed of SiN, SiC, SiOC, or SiO₂.

10. The method according to claim 1, wherein the transmuted surface portions are formed of SiON, SiOC, or SiO₂.

11. The method according to claim 6, wherein the layer is formed of photoresist or SiO₂.

12. The method according to claim 2, wherein when the surface portions are oxidized to form an oxide film, oxidization treatment is performed at a temperature of 400° C. or less.
